(19) United States
(12) Patent Application Publication
(10) Pub. No.: US 2008/0094124 A1
(43) Pub. Date: Apr. 24, 2008

(54) Mosfet Device and Related Method of Operation

(75) Inventors: Keith Heppenstall, Stockport (GB); Adam R. Brown, Bramhall (GB); Ian Kennedy, Stockport (GB); Adrian C.H. Koh, Stockport (GB); Steven T. Peake, Warrington (GB)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: KONINKLIJKE PHILIPS ELECTRONICS N.V., Eindhoven (NL)

(21) Appl. No.: 11/572,913

(22) PCT Filed: Jul. 28, 2005
(86) PCT No.: PCT/IB05/52538

§ 371 Date: Jan. 29, 2007

(30) Foreign Application Priority Data
Jul. 29, 2004 (EP) 0416882.9

(51) Int. Cl. H03K 17/00

(52) U.S. Cl. 327/530

(57) ABSTRACT

The present invention provides for a MOSFET device (10) having a body diode structure (22) and provided with biasing means arranged to provide a bias voltage selectively applied to the gate of the MOSFET (12) during reverse recovery of the body diode structure (22) so as to reduce reverse recovery transient signals associated with the body diode structure (22), the biasing means comprising a diode device (16) located in the gate path of the device (10).

The present invention relates to a MOSFET device and a related method of operation thereof.

An inherent characteristic of a MOSFET comprises a semiconductor p-n diode junction generally identified as the body diode. It is known that semiconductor p-n junction diodes, such as MOSFET body diodes, exhibit non-ideal reverse recovery behaviour when voltage across the conducting p-n junction is reversed.

Due to such reversal of voltage, the forward current previously passing through the junction decays and momentarily reverses before settling at a small constant reverse value.

This momentary reversal and subsequent settling to a small constant reverse value is known as the reverse recovery event and during this event charge stored in the p-n junction is delivered back to the circuit external to that junction. The rate of the subsequent settling determines the “softness” of the reverse recovery. Low settling rates are beneficial because they produce less abrupt transients and consequently less electromagnetic interference.

When in operation, it is found that the body diode is employed in particular for conducting current during specific stages in its operation.

The characteristic of the change in reverse recovery current with time determines the current and voltage transient responses in the surrounding circuit. Also, the magnitude of the reverse current that can flow during the reverse recovery leads to power loss and therefore inefficiency.

Further, the relatively rapid changes in current and voltage comprise transients which represent a potential source of electromagnetic noise generation. Thus, disadvantages of power loss and noise generation, can be seen to arise due to such reverse recovery.

The present invention seeks to provide for a MOSFET device, and related method of operation, having advantages over known such devices, and methods of operation.

According to one aspect of the present invention, there is provided a MOSFET device having a body diode structure and including biasing means arranged to provide a bias voltage selectively applied to the gate of the MOSFET during reverse recovery of the body diode structure so as to reduce reverse recovery transient signals associated with the body diode structure. The biasing means is provided in the form of an impedance, in particular a diode device, located within the gate path of the device.

The invention is particularly advantageous since, through such control of the bias voltage applied to the MOSFET gate during the reverse recovery period of the body diode, it proves possible to improve the characteristics of the body diode within the MOSFET and therefore reduce or eliminate the disadvantages identified above.

The body diode reverse recovery characteristics in particular are enhanced.

In particular, the gate bias voltage is applied in accordance with the present invention so as to improve the apparent “snappiness” of the transient currents and voltages associated with the body diode reverse recovery and which therefore serves to reduce the electrical noise generation.

Preferably, the biasing means is arranged such that the level of the said bias voltage does not exceed the gate-source threshold voltage for unnecessary long periods of time. Employing a gate voltage value in a range between the source potential and the gate-source threshold voltage is considered to be particularly beneficial.

The said biasing means is advantageously arranged to receive current from a drain-gate capacitance of the device and which serves to develop the said bias voltage across the said biasing means.

The biasing means further advantageously is selected so as not to present any significant limitation to the gate current arising during the switching events required of the MOSFET during its normal operations.

The biasing means can advantageously be arranged integrated into the MOSFET structure.

One particularly advantageous embodiment employs a biasing means in the form of a plurality of junction diodes, which, advantageously, can be configured as a series chain of parallel diodes.

Further, the diodes will experience a change with temperature, which is consistent with the manner in which the MOSFET gate source threshold voltage will change with temperature and so provides for self-adjusting of the thermal characteristics of the device.

As an alternative, the impedance can be provided as a resistor-diode combination.

According to another aspect of the present invention, there is provided a method of operating a MOSFET device having a body diode structure and comprising the steps of applying a biasing voltage to the gate of the MOSFET selectively during reverse recovery of the body diode structure so as to reduce the reverse recovery transient signals associated with the body diode structure. An impedance, in particular a diode device, is located within the gate path of the device and can be arranged to receive current from the drain-gate capacitance of the device and which serves to develop the said bias voltage across the said impedance.

Again, the invention is particularly advantageous since, through such control of the bias voltage applied to the MOSFET gate during the reverse recovery period of the body diode, it proves possible to improve the characteristics of the body diode within the MOSFET and therefore advantageously reduce or eliminate the disadvantages identified above.

As before, but in relation to the method, the biasing means can be arranged to limit the level and duration of said bias voltage. Employing a gate voltage value in the range between the source potential and the gate-source threshold voltage is considered to be particularly beneficial.

The invention is described further hereinafter by way of example only with reference to the accompanying drawings in which:

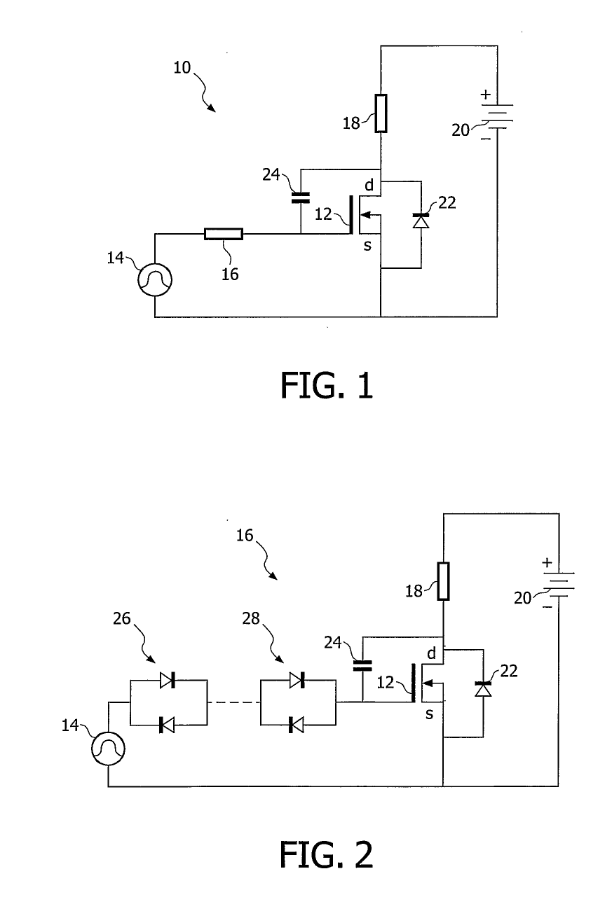

FIG. 1 is a schematic circuit diagram of a MOSFET device according to a general embodiment of the present invention;

FIG. 2 is a schematic circuit diagram of one particular embodiment of a MOSFET device of the present invention; and

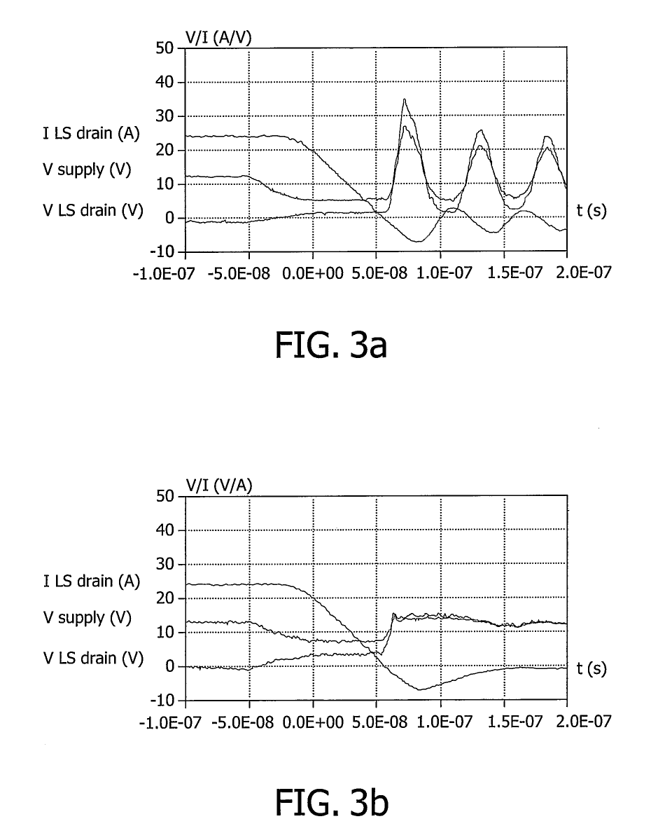

FIGS. 3a and 3b comprise experimental traces obtained from a power MOSFET without and with the reverse recovery enhancement respectively.

Turning first to FIG. 1, there is illustrated in schematic form, a circuit diagram of a MOSFET device 10 embodying the present invention.

In the illustration of the MOSFET device 10 there is shown a MOSFET 12 having a gate arranged to receive a gate drive signal 14 by way of a gate impedance 16 which is provided in accordance with the present invention.

Also illustrated is an operating power supply 20 and associated load 18 connected between the supply 20 and the drain of the MOSFET 12.

As with all MOSFETs, there is a drain-gate capacitance, which is represented by a capacitor 24 within FIG. 1 and also the above-mentioned body diode structure 22 found within the MOSFET 12.

It is known that a body diode current will flow under certain conditions when the load 18 is reactive.

In accordance with the present invention, it is proposed that a bias voltage be applied to the gate of the MOSFET 12 selectively during the reverse recovery within the body diode 22 so as to improve the characteristics thereof.

One particularly advantageous manner of generating the required bias voltage is by way of an impedance 16 as illustrated in FIG. 1.

The impedance 16 is positioned within the gate path of the device to the MOSFET 12.

A positive-going voltage appears on the MOSFET 12 drain when the body diode 22 current reaches zero and it then becomes reversed biased. This generates a current through the drain-gate capacitor 24, which serves to produce a corresponding voltage across the gate impedance 16. The raised gate potential arising in view of the voltage now arising across the impedance 16 serves to effectively soften the reverse recovery transients arising within the body diode.

The nature of the gate impedance 16 has to be selected carefully in order to optimise performance within the MOSFET 12. Ideally, the gate voltage must not be allowed to dwell at voltages near the threshold level for periods greater than that necessary to improve the reverse recovery transient or substantial channel currents may flow. This could incur unnecessary power losses.

It is found that, preferably, a bias voltage applied at the gate at a level somewhere between the source potential and the gate-source threshold voltage level during the reverse recovery event is particularly beneficial.

The use of a gate impedance 16 to provide the required bias voltage at the gate of the MOSFET 12 is further advantageous in that since the current flow from the drain-gate capacitance 24 into the gate impedance 16 is inherently transient by nature of the capacitive coupling, the resulting increase in gate voltage arising across the gate impedance 16 is similarly transient.

Selective application of the said bias gate voltage during reverse recovery within the body diode 22 therefore can be achieved somewhat automatically. Further self limitation within the device also occurs since the formation of a channel within the MOSFET 12 would support a drain-source current that would serve to oppose the rate of change of voltage with time that is causing the gate bias.

Of course, to maintain normal operation during MOSFET switching events, current must be allowed to flow freely between the gate drive 14 and the gate of the MOSFET 12 to control conduction of the channel of the MOSFET 12. The gate impedance 16 therefore must not present a significant limitation to the gate current during the MOSFET switching events if the switching speed capability of the device is to be maintained.

The present invention identifies that there are various ways to implement a suitable gate impedance 16 as illustrated in FIG. 1 and provide for the required functionality.

One particular embodiment is illustrated within FIG. 2 in which like features are identified by the same reference numerals as employed within FIG. 1.

As will be seen, the gate impedance 16 comprises series connected parallel diode chains of which two 26, 28 are shown. Each diode will present a well defined forward voltage drop and the characteristics therefore will also change with temperature in the same way as the MOSFET gate-source threshold voltage will change.

Thus, a degree of self-adjustment having regard to thermal effects advantageously arises within this embodiment of the present invention.

The diode chain 26, 28 may be integrated into the MOSFET structure.

One particular advantage of integrating the diode chain 26, 28 within the semiconductor is that the inductances of the interconnections can be minimised and thermal tracking between the MOSFET 12 and the diode 26, 28 will then be very close.

Of course, as an alternative, different configurations of diodes can be provided and the gate impedance could include integrated resistors within the semiconductor, which can advantageously be formed of polysilicon, or indeed a resistor-diode combination.

Remaining with FIG. 2, the operation of the invention within the MOSFET 12 and as controlled by way of the gate impedance 16 is described with reference to an n-channel MOSFET. In a n-channel MOSFET, the gate-source voltage serves to control the distribution of holes in the p-type semiconductor material adjacent the gate oxide. As will be appreciated, the more positive the gate-source voltage becomes, the more the holes tend to be repelled away from the gate oxide such that electrons then accumulate in this region.

With a small positive gate bias in accordance with the present invention, electrons start to accumulate along the interface between the gate oxide and the semiconductor but such electrons do not accumulate in sufficient quantities to form a significant channel.

When the device body diode 22 is active, the small positive gate bias tends to reduce the area of the zone available for the recombination of holes and electrons at the p-n junction.

Then, the drain-source capacitance 24 becomes effective when a depletion zone forms at the instant of bias polarity reversal across the body diode junction 22.

The overall effect of the small positive bias applied to the gate in accordance with the present invention is to limit the rate at which the drain-source capacitor charges and hence also the rate at which the voltage across the device and current through the device vary with time. This in turn serves to limit consequent electromagnetic noise generation.

Turning now to FIGS. 3a and 3b there are illustrated two experimental traces obtained from a Philips (Generation 4) power MOSFET. In each trace variations in supply voltage, drain current and drain voltage are illustrated.

FIG. 3a shows the resulting traces without the reverse recovery enhancement of the present invention, while FIG. 3b shows the advantageous effect of the application of the present invention.

The clear lengthening of the settling time of the reverse recovery current “undershoot” together with the minimal voltage overshoot and “ringing” without reducing the dl/dt in the device illustrate the benefits of this technique.

The present invention finds ready and advantageous use as a means for controlling so-called third quadrant effect so as to enhance the reverse recovery behaviour.

In further detail, if the MOSFET gate voltage is maintained at a small positive voltage below the threshold level while it is conducting in the reverse direction, i.e. with the body diode in the forward conduction direction, this creates the conditions where reverse recovery charge is reduced due to the ‘Third Quadrant’ (Q3) effect. This is advantageous as it reduces reverse recovery current and therefore power loss.

If this small positive gate bias voltage can be maintained up to the point where the polarity of the current in the MOSFET body diode is at the point of reversing i.e. recovering, the magnitude of the subsequent current in the first quadrant (Q1) can be reduced to such small levels that as there is very little reverse recovery current associated with diode conduction. Importantly, the positive gate bias should be reduced at the correct time to avoid the possibility of Q1 channel current flow resulting in shoot through in MOSFET forward bias conditions. Timing is critical to guarantee optimum operation under all conditions.

The incorporation of the diode structure within the MOSFET structure as described above, together with the inherent MOSFET drain-gate capacitance, produces an automatically timed and limited gate voltage pulse at the instant of body diode reverse recovery dl/dt reversal. This has the effect of permitting a small controlled momentary channel current flow that actively limits drain voltage dV/dt and overshoot and therefore reduces ‘gate bounce’.

As will be appreciated by one skilled in the art, various changes and modifications may be made to the described embodiments, and the present invention may be utilized in may different forms. For example, the biasing diode device may be external or may be integrated within the MOSFET chip, or indeed within the MOSFET driver.

In summary, it should be appreciated that the improvement in the reverse recovery transients is largely independent of body diode current and supply voltage. The use of integrated polysilicon diodes is considered to be a particularly beneficial factor since a relatively short physical connection to the gate can be achieved and can be formed by part of the metalization on the surface of the silicon. As a result, the integrated diodes will exhibit a very low inductance. Also, no further wire bond pads would be needed with such an arrangement.

1. A MOSFET device having a body diode structure and including biasing means arranged to provide a bias voltage selectively applied to the gate of the MOSFET during reverse recovery of the body diode structure so as to reduce reverse recovery transient signals associated with the body diode structure the biasing means comprising a diode device located in the gate path of the device.

2. A device as claimed in claim 1, wherein the biasing means is arranged such that the level of the said bias voltage does not exceed the gate-source threshold voltage.

3. A device as claimed in claim 1, wherein the said diode device comprises a plurality of junction diodes

4. A device as claimed in claim 3, wherein the plurality of junction diodes are configured as a chain of parallel junction diodes.

5. A device as claimed in claim 1, wherein the biasing means comprises a resistor-diode combination.

6. A device as claimed in claim 1, wherein the diode device comprises an integrated polysilicon diode.

7. A device as claimed in claim 1, wherein the biasing means is arranged such that the level of the said bias voltage is in a range between the source potential and the gate-source threshold voltage.

8. A device as claimed in claim 1, wherein the biasing means is arranged to receive current from a drain-gate capacitance within the device to develop the said bias voltage across the biasing means.

9. A device as claimed in claim 8, wherein the drain-gate capacitance comprises the inherent drain-gate capacitance of the MOSFET device.

10. A device as claimed in claim 1, wherein the biasing means is integrated into the MOSFET structure.

11. A method of operating a MOSFET device having a body diode structure and comprising the steps of applying a biasing voltage to the gate of the MOSFET selectively during reverse recovery of the body diode structure so as to reduce the reverse recovery transient signals associated with the body diode structure the biasing voltage being developed by way of a diode device located in the gate path of the device.

12. A method as claimed in claim 11, and including the step of limiting the said bias voltage to a value below the gate-source threshold voltage of the MOSFET device

13. A method as claimed in claim 12, and including the step of limiting the said bias voltage to within a range between the source potential and gate-source threshold voltage of the MOSFET device

14. A method as claimed in claim 11, and including receiving a current from a drain-gate capacitance of the device to develop the said bias voltage across the diode device

15. A method as claimed in claim 14, wherein the said current is received from the inherent drain-gate capacitance of the MOSFET device.

16. A method as claimed in claim 11, and including the step of developing the bias voltage over a plurality of junction diodes

17. A method as claimed in claim 11, and including the step of developing the said bias voltage over a diode resistor combination.
